(19) United States
(12) Patent Application Publication
(10) Pub. No.: US 2026/0062796 A1
(43) Pub. Date: Mar. 5, 2026

(54) APPARATUS FOR COOLING A SPUTTERING TARGET

(71) Applicant: Fraunhofer-Gesellschaft zur Förderung der angewandten Forschung e.V., Munich (DE)

(72) Inventors: Hagen BARTZSCH, Dresden (DE); Dieter WEISKE, Dresden (DE); Dietmar TEMMLER, Dresden (DE); Stefan NEUHAUS, Dresden (DE); Peter FRACH, Dresden (DE); Alexander Martin HINZ, Dresden (DE); Steffen HEICKE, Dresden (DE)

(73) Assignee: Fraunhofer-Gesellschaft zur Förderung der angewandten Forschung e.V., Munich (DE)

(21) Appl. No.: 19/385,821

(22) Filed: Nov. 11, 2025

Related U.S. Application Data
(63) Continuation of application No. PCT/EP2024/061351, filed on Apr. 25, 2024.

(30) Foreign Application Priority Data
May 16, 2023 (DE) 10 2023 112 894.9

(51) Int. Cl. C23C 14/54; C23C 14/34

(52) U.S. Cl. CPC C23C 14/54; C23C 14/3407

(57) ABSTRACT

An apparatus is provided for cooling a sputtering target comprising a heat sink for the sputtering target. The heat sink is traversed by a cooling channel. The cooling channel includes a fluid. A cooling channel outlet is connected to an inlet of a compressor. An outlet of the compressor is connected to the inlet of a pressure stage by a second pipe, a first portion of which extends through a first heat exchanger; the outlet of the pressure stage is connected to the cooling channel inlet by a third pipe; the fluid is a refrigerant having a boiling point of 0° C. or less at a pressure of 1 bar and a boiling point of −10° C. or less at a pressure of 0.7 bar; the pressure stage causes a pressure reduction of at least 2 bars on average from the pressure stage inlet to the pressure stage outlet.

### CROSS-REFERENCE TO RELATED APPLICATIONS

This application is a continuation of international patent application PCT/EP2024/061351 filed Apr. 25, 2024, which claims priority under 35 USC § 119 to German patent application 10 2023 112 894.9 filed May 16, 2023. The entire contents of each of the above-identified applications are hereby incorporated by reference.

### TECHNICAL FIELD

The invention relates to an apparatus for cooling a sputtering target, which can be, for example, a component of a magnetron sputtering device.

### BRIEF DESCRIPTION OF THE DRAWINGS

The embodiments may be better understood with reference to the following drawings and description. The components in the figures are not necessarily to scale.

FIG. 1 is a schematic representation of an apparatus according to the invention;

FIG. 2 is a schematic representation of a first alternative apparatus according to the invention, which includes a heating device;

FIG. 3 is a schematic representation of a second alternative apparatus according to the invention, which includes a heat exchanger; and

FIG. 4 is a schematic representation of a third alternative apparatus according to the invention, in which a compressor is designed as a two-stage compressor.

### DETAILED DESCRIPTION

When depositing thin layers, sputtering processes are often used in which material particles are sputtered from the surface of a target body (hereinafter also called sputtering target) using ion bombardment, thus converted to the vapor phase and then deposited on a substrate to be coated. However, continuous ion bombardment of a sputtering target leads to high thermal stress on the target body. The sputtering target must be cooled to protect it from embrittlement and overheating.

Magnetron sputtering devices are known in which a sputtering target is attached, for example by bonding, to a heat sink which is traversed by at least one cooling channel through which a coolant flows (DE 100 18 858 A1). In this case, the at least one cooling channel can also be designed to be open to the sputtering target on one side, so that the coolant flowing through the cooling channel is in direct contact with the sputtering target, which leads to better heat dissipation. Water is usually used as coolant. However, other liquid or gas coolants flowing through a cooling channel are also known and can be cooled to a temperature below 0 ° C. In such apparatuses, the coolant is often included in a closed cooling circuit, where the coolant heated using the sputtering process in the heat sink is supplied to a heat exchanger in which it releases its thermal energy so that the cooled coolant can be returned to the heat sink. However, such an apparatus often cannot sufficiently cool sputtering target materials having a melting point below 100° C., or cannot cool them in a process-stable manner.

US 2013/0015056 A1 describes apparatuses in which a target is mechanically connected to a cooling plate, where the cooling plate includes a plurality of vessels, open at the top, in which a liquid coolant is stored. The process heat dissipated into the coolant using heat conduction heats the coolant until it evaporates from the vessels. In such an apparatus, heat is dissipated by the evaporation of the coolant.

Finally, U.S. Pat. No. 5,569,361 A discloses apparatuses in which a sputtering target is connected to a cooling plate, where a liquid coolant is sprayed onto the surface of the cooling plate not connected to the sputtering target. Due to the process heat, a portion of the liquid coolant is converted to the vapor state. Heat is removed from the environment during the process of converting a portion of the liquid coolant to the vapor state, resulting in additional cooling performance. However, the disadvantage is that the region of a working chamber within which the coolant is sprayed onto the surface of the cooling plate must be shielded from the rest of the working chamber in a complex manner and pumped out so that the sprayed liquid or evaporated coolant does not contaminate the process zone of the sputtering process.

The invention is therefore based on the technical problem of creating an apparatus for cooling a sputtering target by means of which the disadvantages of the prior art can be overcome. In particular, the apparatus according to the invention should make it possible to cool target materials having a melting temperature below 100° C. in a lasting and efficient manner without the target liquefying.

An apparatus according to the invention for cooling a sputtering target includes a heat sink which has a contact surface by means of which a mechanical contact with the sputtering target is formed. The mechanical contact between the heat sink and the sputtering target is preferably made by means of bonding.

According to the invention, the heat sink is traversed by at least one cooling channel, so that the heat sink has at least one cooling channel inlet and at least one cooling channel outlet, and where a fluid flows through the cooling channel. In an apparatus according to the invention, however, the cooling effect is based not only on the fact that thermal energy of the sputtering target is first dissipated by thermal conduction into the heat sink and there into the cold fluid flowing through the cooling channel, but in an apparatus according to the invention, the fluid flowing through the cooling channel is in the form of a refrigerant.

According to DIN EN 378-1, paragraph 3.7.1, a refrigerant is defined as a “fluid used for heat transfer in a refrigerating system which absorbs heat at a low temperature and a low pressure and releases heat at a higher temperature and a higher pressure, usually involving changes in the state of the fluid. ”

While a coolant within a cooling circuit known from the prior art can only transport cold in the form of a cold coolant or dissipate thermal energy with the coolant, a refrigerant can extract thermal energy from an environment during the change in state of the refrigerant from the liquid state to the gas or vapor state.

In an apparatus according to the invention, a refrigerant used undergoes at least a partial change in state from liquid to vapor or gas, predominantly within the cooling channel in the heat sink, due to the thermal energy introduced into the target and the heat sink using a sputtering process, where thermal energy is extracted from the environment of the refrigerant due to the change in the state of the refrigerant. The use of a refrigerant is also advantageous in that the turbulent flow of the liquid-vapor mixture of a refrigerant within the cooling channel contributes to improved heat transfer between the refrigerant and the heat sink compared to a laminar flow of a cooling liquid known from the prior art.

Furthermore, in an apparatus according to the invention, the heat input into a refrigerant leads only, if at all, to insignificant heating of the refrigerant itself. Due to the above-mentioned circumstances, an apparatus according to the invention can achieve greater cooling performance compared to known apparatuses in which a fluid is only conveyed through a cooling channel without a change in state.

Refrigerants known from the prior art which are suitable for use in an apparatus according to the invention have a boiling point of 0 ° C. or less at a pressure of 1 bar and a boiling point of −10° C. or less at a pressure of 0.7 bar. It is particularly advantageous for a refrigerant to be used which has a boiling point of −40° C. or lower at a pressure of 1 bar and a boiling point of −50° C. or lower at a pressure of 0.7 bar. When using such a refrigerant, sputtering target materials having a melting temperature in the range of −40° C. to +200° C. can also be efficiently cooled, such as, for example, sputtering targets including at least one of the chemical elements gallium, indium and/or mercury.

An apparatus according to the invention further includes at least one compressor, by means of which the vapor components of the refrigerant which escape from the cooling channel of the heat sink are compressed and finally converted back to the liquid state. The cooling channel outlet of the heat sink is therefore connected to the inlet of the compressor by means of a first pipe. The outlet of the compressor is connected to the inlet of a pressure stage by means of a second pipe and a third pipe finally connects the outlet of the pressure stage to the cooling channel inlet. In the sense of the invention, a pressure stage is to be regarded as devices by means of which a change in pressure of a fluid flowing through the pressure stage from the inlet of the device to the outlet of the device can be effected. A nozzle or a controllable valve can be used as a pressure stage, for example.

The pressure stage of an apparatus according to the invention is dimensioned or configured in such a way that a pressure reduction of at least 2 bar is effected on average over time from the inlet of the pressure stage to the outlet of the pressure stage. In a preferred embodiment, a pressure reduction of at least 8 bar is effected on average over time from the inlet of the pressure stage to the outlet of the pressure stage. Due to the pressure reduction, first liquid components of the refrigerant are converted from the liquid to the vapor state after flowing through the pressure stage. It is therefore advantageous for the pressure stage within the cooling circuit to be arranged as close as possible to the cooling channel inlet or, alternatively, to be formed within the heat sink so that the majority of the liquid components of the refrigerant undergo a change in state from the liquid state to the vapor state within the cooling channel.

An apparatus according to the invention thus includes a closed cooling circuit through which flows a liquid-vapor mixture of a refrigerant. The refrigerant has the highest proportion of liquid components within the second pipe after leaving the compressor, which then decreases within the third pipe and within the cooling channel. Within the first pipe immediately prior to the refrigerant entering the compressor, the refrigerant preferably no longer contains any liquid components, because liquid components flowing into a compressor can negatively affect the functionality of the compressor.

After leaving the compressor, the refrigerant has a relatively high temperature, which must be lowered again before the refrigerant flows into the heat sink. In an apparatus according to the invention, therefore, at least a first portion of the second pipe extends through a first heat exchanger in which the heat of the refrigerant is transferred to a coolant, such as water.

Because the power input into a sputtering target during a sputtering process is not always constant and therefore in phases of low sputtering power or no sputtering power at all there may not be enough process heat available to convert all liquid components of the refrigerant to the vapor state, it is advantageous for the cooling circuit in the region of the first pipe to still have a thermal base load, which ensures that all components of the refrigerant are converted to the vapor state prior to entering the compressor. Such a thermal base load can be provided, for example, by means of a heating device which heats at least a portion of the first pipe and the refrigerant located therein.

Alternatively, the thermal base load can also be provided by means of a second heat exchanger. The temperature of the refrigerant decreases by the same measure as the liquid components of the refrigerant decrease from the second pipe through the third pipe and the cooling channel to the first pipe. This means that the refrigerant has the highest temperature within the second pipe and the lowest temperature within the first pipe. When using a second heat exchanger for the thermal base load within the first pipe, a second portion of the second pipe can therefore be in heat exchange with a portion of the first pipe.

It is advantageous to design the cross-section of the cooling channel and the cross-section of the first pipe with a surface area of 2 cm² or larger in order to keep the temperature and pressure of the refrigerant as low as possible.

In order to ensure the best possible heat exchange between the heat sink and the refrigerant, it is advantageous for the contact surface of the refrigerant with the heat sink to be as large as possible. In an apparatus according to the invention, the contact surface of the refrigerant with the heat sink corresponds to the cooling channel outer surface. The total size of the cooling channel outer surface can be adjusted, for example, via the length of the cooling channel and/or the number of cooling channels. In a further embodiment of the invention, the cooling channel outer surface area is at least three times as large as the surface of the sputtering target used for sputtering.

The invention is explained in greater detail below using exemplary embodiments.

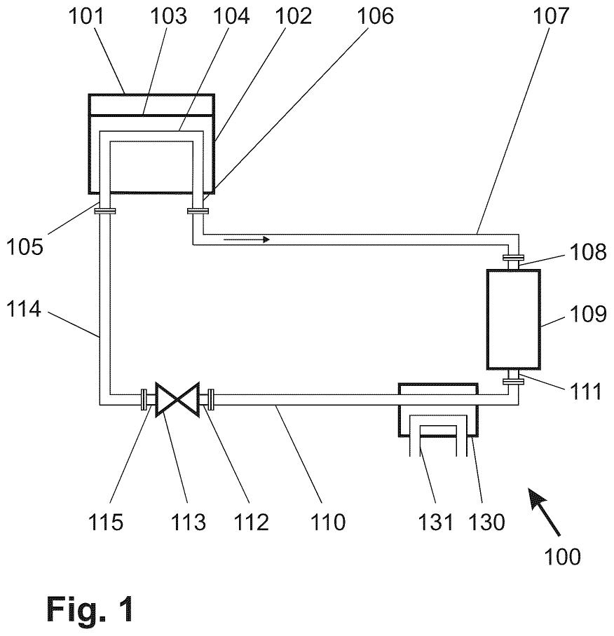

In FIG. 1, an apparatus 100 according to the invention for cooling a sputtering target 101 is shown schematically. The apparatus 100 includes a heat sink 102 having a contact surface 103, where the contact surface 103 forms a mechanical contact with the sputtering target 101. The mechanical contact between the contact surface 103 and the sputtering target is preferably made by means of bonding. The heat sink 102 is traversed by a cooling channel 104, so that the heat sink 102 has a cooling channel inlet 105 and a cooling channel outlet 106. The cooling channel 104 is preferably designed with a cross-section of 2 cm² or larger and a fluid for cooling the heat sink flows therethrough, where the fluid is formed according to the invention as a refrigerant.

By means of a first pipe 107, which is preferably designed with a cross-section of 2 cm² or larger, the cooling channel outlet 106 is connected to an inlet 108 of a compressor 109 (hereinafter also referred to as compressor inlet 108). A second pipe 110 connects an outlet 111 of the compressor 109 (hereinafter also referred to as compressor outlet 109) to an inlet 112 of a pressure stage 113 (hereinafter also referred to as pressure stage inlet 112). And by means of a third pipe 114, an outlet 115 of the pressure stage 113 (hereinafter also referred to as pressure stage outlet 115) is connected to the cooling channel inlet 105, thereby forming a closed cooling circuit through which the refrigerant flows. An arrow inside the first pipe indicates the flow direction of the refrigerant within the cooling circuit.

The sputtering target 101 and the heat sink 102 are usually arranged within a working chamber, which can be designed, for example, as a vacuum chamber. Within the working chamber, during a sputtering process, material particles are typically sputtered from the sputtering target 101 and deposited on at least one substrate. For reasons of clarity, the working chamber and a substrate to be coated are not shown in FIG. 1.

According to the invention, a fluid which has a boiling point of 0 ° C. or less at a pressure of 1 bar and a boiling point of −10° C. or less at a pressure of 0.7 bar is used as the refrigerant flowing through the cooling channel 104. Such refrigerants are known from the prior art, such as the refrigerant R449A, for example.

Within the second pipe 110, after exiting the compressor 109, the refrigerant within the cooling circuit has the highest temperature and the highest proportion of liquid components.

In order to cool the refrigerant after it leaves the compressor, a first portion of the second pipe 110 extends through a first heat exchanger 130, within which thermal energy from the refrigerant is transferred to a cooling liquid that flows through a cooling line 131. Water can be used as a cooling liquid, for example.

The pressure of the refrigerant is reduced as it subsequently flows through the pressure stage 113. For this purpose, the pressure stage is dimensioned according to the invention such that the pressure stage 113 from the pressure stage inlet 112 to the pressure stage outlet 115 effects a pressure reduction of at least 2 bar on average over time. The pressure stage 113 can be designed, for example, as a controllable valve in which the flow rate is controlled as a function of the pressure and/or as a function of the temperature within the pipe system.

However, a pressure reduction can also be effected or supported by selecting a pipe cross-section of the third pipe 114 that is larger than the pipe cross-section of the second pipe 110. Due to the pressure reduction, first liquid components of the refrigerant are converted from the liquid to the vapor state after flowing through the pressure stage 113. It is therefore advantageous if the third pipe 114 is dimensioned as short as possible. The heat introduced into the sputtering target 101 by the sputtering process passes through the contact surface 103 into the heat sink 102 by heat conduction and ultimately also heats the refrigerant flowing through the cooling channel 104. Due to the thermal energy introduced by heat conduction into the refrigerant within the cooling channel 104, further components of the refrigerant within the cooling channel 104 undergo a change of state from the liquid state to the vapor or gas state. Due to this change in the state of the refrigerant within the cooling channel 104, heat is extracted from the environment, which contributes to the cooling of the heat sink 102 and ultimately also to the cooling of the sputtering target 101.

By means of such an apparatus 100 according to the invention, sputtering targets can be cooled better than with cooling apparatuses according to the prior art in which the thermal energy of a sputtering process is introduced into a cooling fluid merely by thermal conduction without a change in state. If a refrigerant known from the prior art is selected which has a boiling point of −40° C. or lower at a pressure of 1 bar and a boiling point of −60° C. or lower at a pressure of 0.7 bar, a sputtering target 101 including the materials gallium, indium and/or mercury can also be cooled with an apparatus 100 according to the invention, thereby enabling a long-term stable sputtering process of these materials without liquefaction of the target.

The following are merely examples of temperature values that are or can be set within an apparatus according to the invention in a previously described structure:
Refrigerant in the cooling channel 104: −50° C.,
Refrigerant within the first pipe 107: −60° C.,
Refrigerant after leaving compressor 109: 40° C.,
Refrigerant after passing through the first heat exchanger 130: 25° C.,
Refrigerant downstream of the pressure level 113: −40° C.,
Target 101 on its surface: 20° C.,
Target 101 at the interface 103 to the heat sink 102: 0° C.,
Heat sink 102: −5° C.

All components of the refrigerant are preferably converted to the vapor or gas state prior to entering the compressor 109. Within the compressor 109, the vapor or gas components of the refrigerant are compressed and converted to the liquid state, so that the cooling cycle can begin again after the liquefied refrigerant exits the compressor 109.

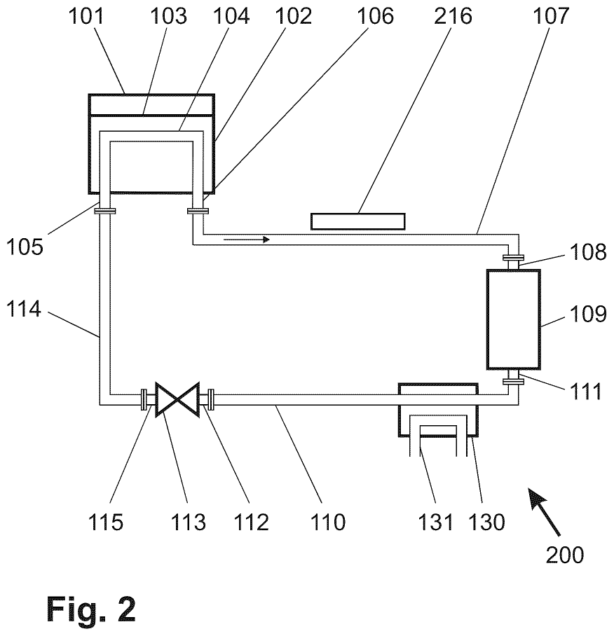

A first alternative apparatus 200 for cooling the sputtering target 101 is shown schematically in FIG. 2. The apparatus 200 initially includes all components and functionalities as described for the apparatus 100 in FIG. 1. In addition, the apparatus 200 has a heating device 216, by means of which at least a portion of the first pipe 107, and thus also the refrigerant flowing through this portion can be heated. The heating device 216 can be designed, for example, as a radiant heater, as a heating coil through which current flows and which is wound about the first pipe 107, or as a heating coil through which a warm fluid flows and which is wound about the first pipe. Since performance fluctuations or process pauses which lead to irregularities in the process-related heat input into the heat sink can occur during the sputtering process, the heating device 216 as a thermal base load ensures that at all times during the sputtering process all components of the refrigerant are converted to the vapor or gas state prior to entering the compressor 109, so that the compressor 109 is not damaged by liquid refrigerant components.

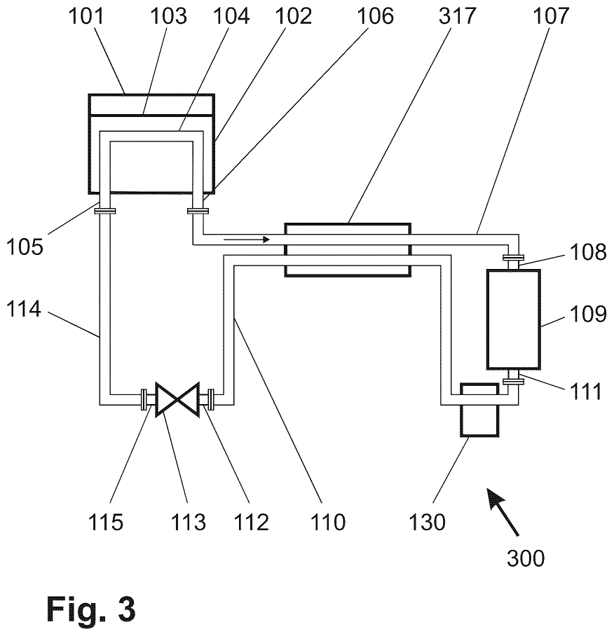

A second alternative apparatus 300 for cooling the sputtering target 101 is shown schematically in FIG. 3. The apparatus 300 initially includes all components and functionalities as described for apparatus 100 in FIG. 1. In addition, the apparatus 300 includes a second heat exchanger 317 through which a portion of the first pipe 107 and a second portion of the second pipe 110 extend. As previously explained, the refrigerant within the second pipe 110 has a higher temperature than the refrigerant within the first pipe 107. In the embodiment according to apparatus 300, thermal energy of the refrigerant from the second pipe 110 is therefore used to heat the refrigerant within the first pipe 107 to ensure that all components of the refrigerant are converted to the vapor or gas state prior to entering the compressor 109. Apparatus 300 of FIG. 3 is more energy efficient than apparatus 200 of FIG. 2, since in the apparatus 300 no additional energy has to be supplied for heating the refrigerant within the first pipe 107. Alternatively, but also in addition to the second heat exchanger 317, a heating device according to the heating device 216 from FIG. 2 can be installed in the cooling circuit.

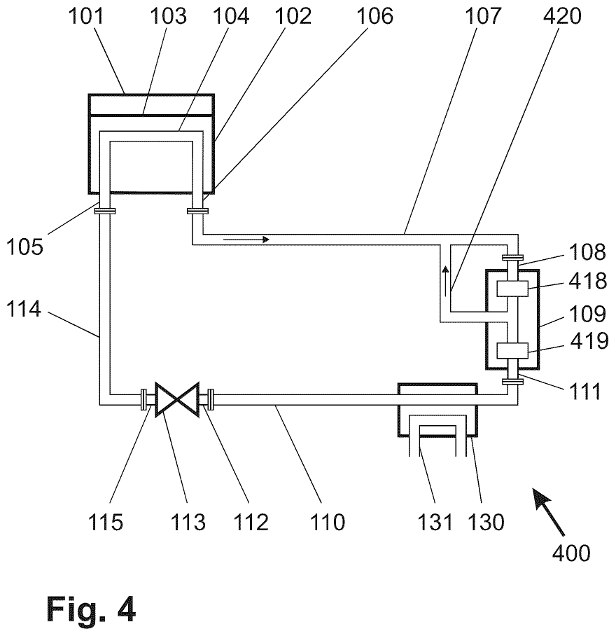

A third alternative apparatus 400 for cooling the sputtering target 101 is shown schematically in FIG. 4. The apparatus 400 initially includes all components and functionalities as described for apparatus 100 in FIG. 1. In apparatus 400, the compressor 109 is designed as a two-stage compressor such that it includes a compressor 418 as the first assembly and a condenser 419 as the second assembly. The vapor or gas components of the refrigerant flowing into the compressor 109 are initially only compressed by means of the compressor 418, and this occurs along with an increase in the temperature of the refrigerant. The compressed vapor or gas components of the refrigerant are then converted to the liquid state by means of the condenser 419. In the apparatus 400, a fourth pipe 420 connects the outlet of the compressor 418 to the first pipe 107, so that within the compressor 109, a portion of the compressed refrigerant which is still vaporous or gaseous, after passing through the compressor 418, is tapped by means of the fourth pipe 420 and introduced into the first pipe 107. The supply of the compressed and heated refrigerant to the pipe 107 also results in all components of the refrigerant within the first pipe being converted to the vapor or gas state prior to entering the compressor 109. It is advantageous for the amount of the portion of the refrigerant tapped after passing through the compressor 418 to be controlled as a function of the amount of process heat introduced into the refrigerant within the heat sink.

For the sake of completeness, it should be noted that the assemblies or components known from FIG. 2 to 4 that go beyond the assemblies and components known from FIG. 1 can be combined with one another as desired in further exemplary embodiments.

To clarify the use of and to hereby provide notice to the public, the phrases “at least one of <A>, <B>, . . . and <N>” or “at least one of <A>, <B>, . . . or <N>” or “at least one of <A>, <B>, . . . <N>, or combinations thereof” or “<A>, <B>, . . . and/or <N>” are defined by the Applicant in the broadest sense, superseding any other implied definitions hereinbefore or hereinafter unless expressly asserted by the Applicant to the contrary, to mean one or more elements selected from the group comprising A, B, . . . and N. In other words, the phrases mean any combination of one or more of the elements A, B, . . . or N including any one element alone or the one element in combination with one or more of the other elements which may also include, in combination, additional elements not listed. Unless otherwise indicated or the context suggests otherwise, as used herein, “a” or “an” means “at least one” or “one or more.”

1. An apparatus for cooling a sputtering target, the apparatus comprising a heat sink which has a contact surface configured to form a mechanical contact with the sputtering target, wherein the heat sink is traversed by a cooling channel, wherein the heat sink includes a cooling channel inlet and a cooling channel outlet, and wherein the cooling channel comprises a fluid flowable through the cooling channel, wherein
the cooling channel outlet is connected to an inlet of a compressor by a first pipe;
an outlet of the compressor is connected to the inlet of a pressure stage by a second pipe;
a first portion of the second pipe extends through a first heat exchanger;
the outlet of the pressure stage is connected to the cooling channel inlet by a third pipe;
the fluid is in the form of a refrigerant; wherein the refrigerant has a boiling point of 0° C. or less at a pressure of 1 bar and a boiling point of −10° C. or less at a pressure of 0.7 bar;
and the pressure stage is configured to affect a pressure reduction of at least 2 bars on average over time from a pressure stage inlet to a pressure stage outlet.

2. The apparatus of claim 1, wherein the refrigerant has a boiling point of −40° C. or less at a pressure of 1 bar and a boiling point of −50° C. or less at a pressure of 0.7 bar.

3. The apparatus of claim 1 comprising a heating device configured to heat at least a portion of the first pipe.

4. The apparatus of claim 3, wherein the heating device includes a radiant heater or a heating coil through which current flows.

5. The apparatus of claim 1 comprising a second heat exchanger through which a portion of the first pipe and a second portion of the second pipe extend.

6. The apparatus of claim 1, wherein the pressure stage includes a nozzle or a controllable valve.

7. The apparatus of claim 1, wherein the first pipe has a cross-section of 2 cm² or larger.

8. The apparatus of claim 1, wherein the sputtering target comprises gallium, indium and/or mercury.

9. The apparatus of claim 1, wherein the sputtering target is bonded to the heat sink.

10. The apparatus of claim 1, wherein an outer surface of the cooling channel is at least three times as large as a surface of the sputtering target.

11. The apparatus of claim 10, wherein the cooling channel has a cross-section of 2 cm² or larger.

12. The apparatus of claim 1, wherein the compressor is a two-stage compressor comprising a compressor as a first assembly and a condenser as a second assembly, wherein a fourth pipe connects an outlet of the compressor to the first pipe.
